(19) United States
(12) Patent Application Publication
(10) Pub. No.: US 2013/0136862 A1
(43) Pub. Date: May 30, 2013

(54) MULTI-CELL MOCVD APPARATUS

(71) Applicant: Peter Satitpunwaycha, Sunnyvale, CA (US)

(72) Inventor: Peter Satitpunwaycha, Sunnyvale, CA (US)

(73) Assignee: Intermolecular, Inc., San Jose, CA (US)

(21) Appl. No.: 13/307,811

(22) Filed: Nov. 30, 2011

(51) Int. Cl. C23C 14/00; C23C 16/00

(52) U.S. Cl. 427/255.7; 118/719; 118/712

(57) ABSTRACT

A plurality of independent reaction cells are disposed within a single process module to allow the deposition of films using MOCVD wherein parameters of the deposition are varied in a combinatorial manner. In some embodiments of the present invention, a plurality of independent reaction cells are disposed within a isolated process modules configured in a linear fashion to allow the deposition of films using MOCVD wherein parameters of the deposition are varied in a combinatorial manner. The independent reaction cells may also be utilized to form multilayer film stacks that are varied in a combinatorial manner.

### FIELD OF THE INVENTION

The present invention relates generally to systems for high productivity combinatorial materials screening using chemical vapor deposition processes. A specific example will include systems for high productivity combinatorial materials screening using metal organic chemical vapor deposition processes.

### BACKGROUND OF THE INVENTION

The manufacture of integrated circuits (IC), semiconductor devices, flat panel displays, optoelectronics devices, data storage devices, magneto-electronic devices, magneto-optic devices, packaged devices, and the like entails the integration and sequencing of many unit processing steps. As an example, IC manufacturing typically includes a series of processing steps such as cleaning, surface preparation, deposition, lithography, patterning, etching, planarization, implantation, thermal annealing, and other related unit processing steps. The precise sequencing and integration of the unit processing steps enables the formation of functional devices meeting desired performance metrics such as speed, power consumption, and reliability.

As part of the discovery, optimization and qualification of each unit process, it is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices such as integrated circuits. In particular, there is a need to be able to test i) more than one material, ii) more than one processing condition, iii) more than one sequence of processing conditions, iv) more than one process sequence integration flow, and combinations thereof, collectively known as “combinatorial process sequence integration”, on a single monolithic substrate without the need of consuming the equivalent number of monolithic substrates per material(s), processing condition(s), sequence(s) of processing conditions, sequence(s) of processes, and combinations thereof. This can greatly improve both the speed and reduce the costs associated with the discovery, implementation, optimization, and qualification of material(s), process(es), and process integration sequence(s) required for manufacturing.

Systems and methods for High Productivity Combinatorial (HPC) processing are described in U.S. Pat. No. 7,544,574 filed on Feb. 10, 2006, U.S. Pat. No. 7,824,935 filed on Jul. 2, 2008, U.S. Pat. No. 7,871,928 filed on May 4, 2009, U.S. Pat. No. 7,902,063 filed on Feb. 10, 2006, and U.S. Pat. No. 7,947,531 filed on Aug. 28, 2009 which are all herein incorporated by reference. Systems and methods for HPC processing are further described in U.S. patent application Ser. No. 11/352,077 filed on Feb. 10, 2006, claiming priority from Oct. 15, 2005, U.S. patent application Ser. No. 11/419,174 filed on May 18, 2006, claiming priority from Oct. 15, 2005, U.S. patent application Ser. No. 11/674,132 filed on Feb. 12, 2007, claiming priority from Oct. 15, 2005, and U.S. patent application Ser. No. 11/674,137 filed on Feb. 12, 2007, claiming priority from Oct. 15, 2005 which are all herein incorporated by reference.

HPC processing techniques have been successfully adapted to wet chemical processing such as etching and cleaning. HPC processing techniques have also been successfully adapted to deposition processes such as physical vapor deposition (PVD), atomic layer deposition (ALD), and chemical vapor deposition (CVD). However, the HPC systems used for development of PVD, ALD, and CVD processes have not implemented a variable for rotation within each site isolated region.

One class of deposition methods that has not been successfully adapted to HPC processing techniques involves the use of metal organic chemical vapor deposition (MOCVD) technologies for the deposition of thin films. Issues arise in the adaptation of HPC techniques to MOCVD technologies due to the high temperatures and corrosive gases that are typical of MOCVD processes. Additionally, rotation is often an important variable in the development of MOCVD processes.

MOCVD processes are used for the deposition of a number of important materials and devices. MOCVD is used in the formation of III-V materials such as GaAs, GaAlAs, InP, GaP, GaN, etc. MOCVD is also used in the formation of II-VI materials such as CdTe, CdS, ZnSe, ZnS, etc. These materials are used in devices such as compound semiconductor ICs, solar cells, light emitting diodes (LED), solid state lasers, etc. These materials are expensive and the development times can be long.

Therefore, there is a need to develop systems that allow HPC processing techniques to include a rotation variable within each site isolated region. There is an additional need to develop systems that allow HPC processing techniques to be adapted to MOCVD deposition processes to improve the efficiency of development activities and lower the costs of development activities.

### SUMMARY OF THE DISCLOSURE

The following summary of the invention is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

In some embodiments of the present invention, a plurality of independent reaction cells are disposed within a single process module to allow the deposition of films using MOCVD wherein parameters of the deposition are varied in a combinatorial manner. In some embodiments of the present invention, a plurality of independent reaction cells are disposed within a isolated process modules configured in a linear fashion to allow the deposition of films using MOCVD wherein parameters of the deposition are varied in a combinatorial manner.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 is a schematic diagram for implementing combinatorial processing and evaluation.

FIG. 2 is a schematic diagram for illustrating various process sequences using combinatorial processing and evaluation.

FIG. 3 is a simplified schematic diagram illustrating an integrated high productivity combinatorial (HPC) system in accordance with some embodiments of the invention.

FIG. 4 is a schematic diagram for implementing high productivity combinatorial processing for MOCVD processes in accordance with some embodiments of the invention.

FIG. 5 is a schematic diagram for implementing high productivity combinatorial processing for MOCVD processes in accordance with some embodiments of the invention.

FIG. 6 is a schematic diagram for a single reactor cell for implementing high productivity combinatorial processing for MOCVD processes in accordance with some embodiments of the invention.

FIG. 7 is a schematic diagram for a single reactor cell for implementing high productivity combinatorial processing for MOCVD processes in accordance with some embodiments of the invention.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

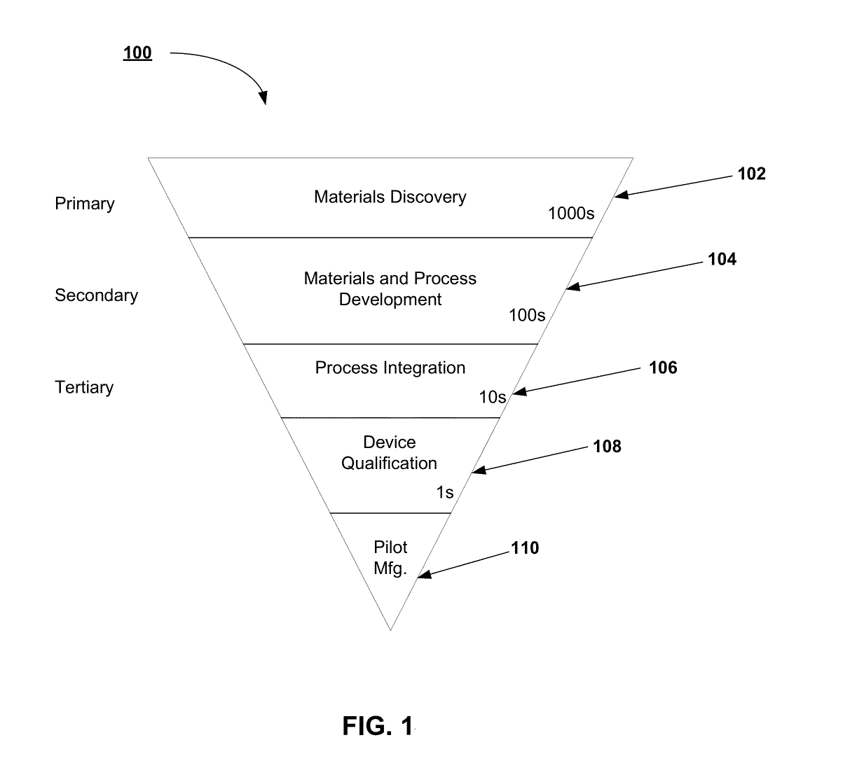

FIG. 1 illustrates a schematic diagram, 100, for implementing combinatorial processing and evaluation using primary, secondary, and tertiary screening. The schematic diagram, 100, illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage, 102. Materials discovery stage, 102, is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage, 104. Evaluation of the materials is performed using metrology tools such as electronic testers and imaging tools (i.e., microscopes).

The materials and process development stage, 104, may evaluate hundreds of materials (i.e., a magnitude smaller than the primary stage) and may focus on the processes used to deposit or develop those materials. Promising materials and processes are again selected, and advanced to the tertiary screen or process integration stage, 106, where tens of materials and/or processes and combinations are evaluated. The tertiary screen or process integration stage, 106, may focus on integrating the selected processes and materials with other processes and materials.

The most promising materials and processes from the tertiary screen are advanced to device qualification, 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing, 110.

The schematic diagram, 100, is an example of various techniques that may be used to evaluate and select materials and processes for the development of new materials and processes. The descriptions of primary, secondary, etc. screening and the various stages, 102-110, are arbitrary and the stages may overlap, occur out of sequence, be described and be performed in many other ways.

This application benefits from High Productivity Combinatorial (HPC) techniques described in U.S. patent application Ser. No. 11/674,137 filed on Feb. 12, 2007 which is hereby incorporated for reference in its entirety. Portions of the '137 application have been reproduced below to enhance the understanding of the present invention. The embodiments described herein enable the application of combinatorial techniques to process sequence integration in order to arrive at a globally optimal sequence of semiconductor devices, TFPV modules, optoelectronic devices, etc. manufacturing operations by considering interaction effects between the unit manufacturing operations, the process conditions used to effect such unit manufacturing operations, hardware details used during the processing, as well as materials characteristics of components utilized within the unit manufacturing operations. Rather than only considering a series of local optimums, i.e., where the best conditions and materials for each manufacturing unit operation is considered in isolation, the embodiments described below consider interactions effects introduced due to the multitude of processing operations that are performed and the order in which such multitude of processing operations are performed when fabricating a semiconductor devices, TFPV modules, optoelectronic devices, etc. device. A global optimum sequence order is therefore derived and as part of this derivation, the unit processes, unit process parameters and materials used in the unit process operations of the optimum sequence order are also considered.

The embodiments described further analyze a portion or sub-set of the overall process sequence used to manufacture semiconductor devices, TFPV modules, optoelectronic devices, etc. Once the subset of the process sequence is identified for analysis, combinatorial process sequence integration testing is performed to optimize the materials, unit processes, hardware details, and process sequence used to build that portion of the device or structure. During the processing of some embodiments described herein, structures are formed on the processed substrate that are equivalent to the structures formed during actual production of the semiconductor devices, TFPV modules, optoelectronic devices, etc. For example, such structures may include, but would not be limited to, contact layers, buffer layers, absorber layers, or any other series of layers or unit processes that create an intermediate structure found on semiconductor devices, TFPV modules, optoelectronic devices, etc. While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete region. Furthermore, while different materials or unit processes may be used for corresponding layers or steps in the formation of a structure in different regions of the substrate during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete regions on the substrate can be defined as needed, but are preferably systematized for ease of tooling and design of experimentation. In addition, the number, variants and location of structures within each region are designed to enable valid statistical analysis of the test results within each region and across regions to be performed.

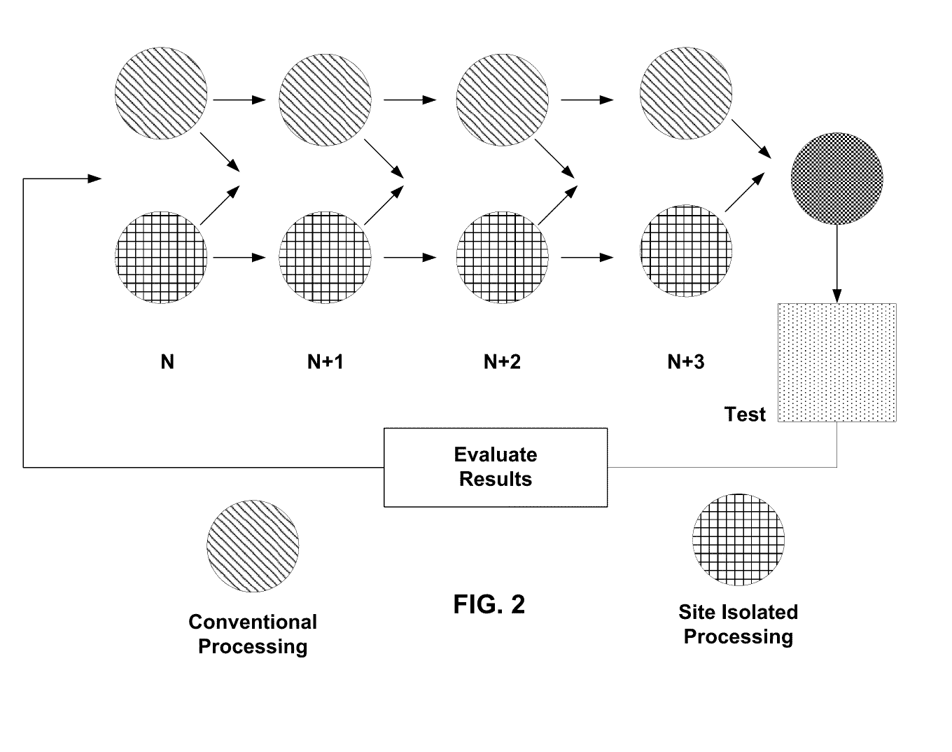

FIG. 2 is a simplified schematic diagram illustrating a general methodology for combinatorial process sequence integration that includes site isolated processing and/or conventional processing in accordance with one embodiment of the invention. In one embodiment, the substrate is initially processed using conventional process N. In one exemplary embodiment, the substrate is then processed using site isolated process N+1. During site isolated processing, an HPC module may be used, such as the HPC module described in U.S. patent application Ser. No. 11/352,077 filed on Feb. 10, 2006. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in semiconductor device, TFPV module, optoelectronic device, etc. manufacturing may be varied.

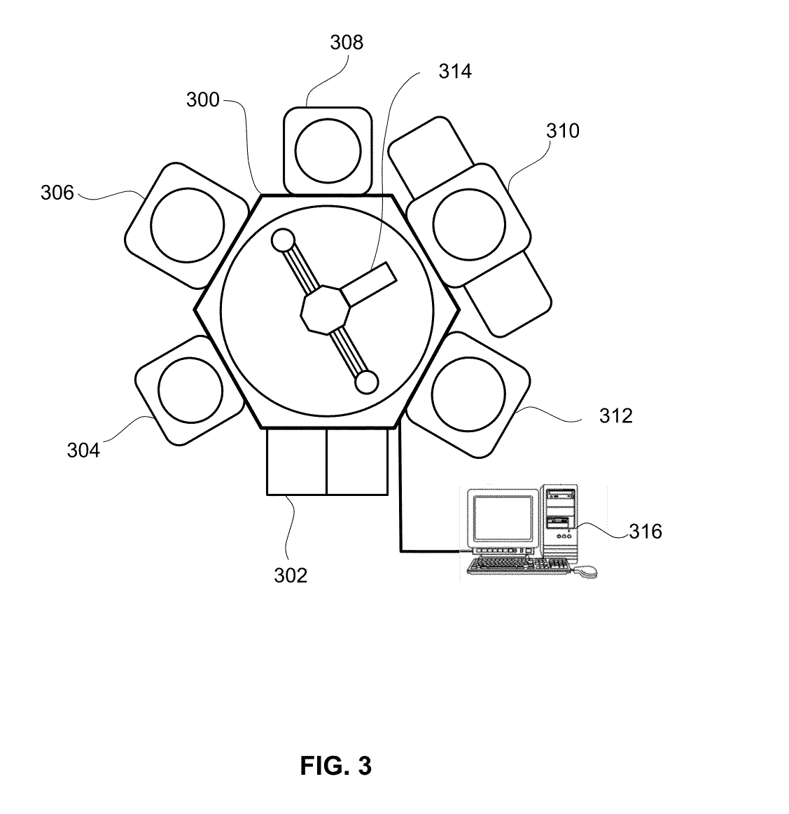

FIG. 3 is a simplified schematic diagram illustrating an integrated high productivity combinatorial (HPC) system in accordance with some embodiments of the invention. HPC system includes a frame 300 supporting a plurality of processing modules. It should be appreciated that frame 300 may be a unitary frame in accordance with some embodiments. In some embodiments, the environment within frame 300 is controlled. Load lock/factory interface 302 provides access into the plurality of modules of the HPC system. Robot 314 provides for the movement of substrates (and masks) between the modules and for the movement into and out of the load lock 302. Modules 304-312 may be any set of modules and preferably include one or more combinatorial modules. For example, module 304 may be an orientation/degassing module, module 306 may be a clean module, either plasma or non-plasma based, modules 308 and/or 310 may be combinatorial/conventional dual purpose modules. Module 312 may provide conventional clean or degas as necessary for the experiment design.

Any type of chamber or combination of chambers may be implemented and the description herein is merely illustrative of one possible combination and not meant to limit the potential chamber or processes that can be supported to combine combinatorial processing or combinatorial plus conventional processing of a substrate or wafer. In some embodiments, a centralized controller, i.e., computing device 316, may control the processes of the HPC system, including the power supplies and synchronization of the duty cycles described in more detail below. Further details of one possible HPC system are described in U.S. application Ser. No. 11/672,478 filed Feb. 7, 2007, now U.S. Pat. No. 7,867,904 and claiming priority to U.S. Provisional Application No. 60/832,248 filed on Jul. 19, 2006, and U.S. application Ser. No. 11/672,473, filed Feb. 7, 2007 and claiming priority to U.S. Provisional Application No. 60/832,248 filed on Jul. 19, 2006, which are all herein incorporated by reference. With HPC system, a plurality of methods may be employed to deposit material upon a substrate employing combinatorial processes.

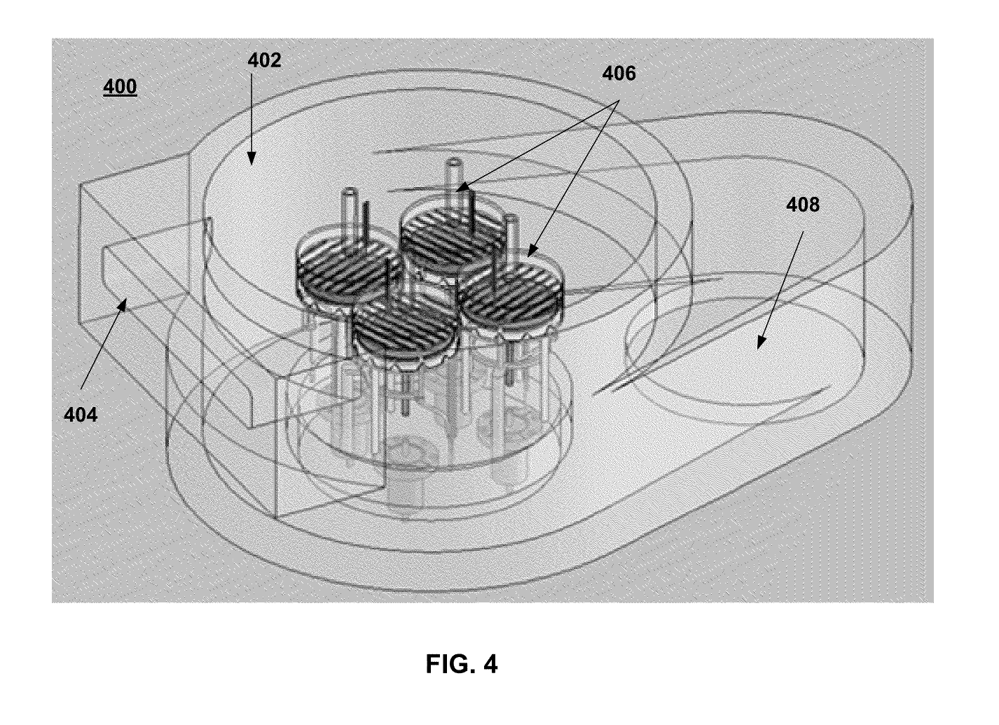

FIG. 4 is a schematic diagram for implementing high productivity combinatorial processing for MOCVD processes in accordance with some embodiments of the invention. FIG. 4 illustrates a single module, 400, that may be part of a HPC system as described in reference to FIG. 3. That is, module, 400, may be one of the modules, 304-312, as discussed with reference to FIG. 3. Module, 400, comprises a chamber enclosure, 402, that defines the vacuum environment. The module would connect with the system (300 in FIG. 3) via the interface, 404. The interface allows substrates to pass between the module and the transfer chamber comprising the robot (314 in FIG. 3). Illustrated in FIG. 4 are four MOCVD reaction cells, 406, which will be described in more detail below. Therefore, the four reaction cells share the module space and the module exhaust system, but are otherwise independent. Although four are illustrated in FIG. 4, those skilled in the art will understand that any number of MOCVD reaction cells may be integrated into module, 400, limited only by practical considerations such as size, etc. Also illustrated in FIG. 4 is a vacuum port, 408, which is connected to a vacuum system (not shown) that is used to control the pressure of the module. The MOCVD depositions envisioned herein are all made a sub-atmospheric pressure and require a system to form a vacuum within the process module. The basic architecture of the module and supporting systems is well known in the art. The details of the reaction cells are novel and will be described in more detail below.

As discussed previously, the four reaction cells, 406, are independent and may be used to process substrates in a combinatorial manner. Parameters that may be varied combinatorially between the various reaction cells comprise material, temperature, gas flow rate, gas composition, rotation speed, etc. Furthermore, the substrates may be moved between the various reaction cells to enable multilayer depositions. The multiple reaction cells may be used to process multiple substrates in a combinatorial manner with regard to a single material. That is, process parameters may be varied amongst the various independent reaction cells wherein all of the reaction cells are depositing the same material. Alternatively, each of the independent reaction cells may be used to deposit a different material and the material and/or composition may be varied in a combinatorial manner amongst the various independent reaction cells. Alternatively, each of the independent reaction cells may be used to deposit a different material and a sequence of processes may be varied by altering the sequence in which the substrates are moved between the various reaction cells. The sequence of processes may be varied in a combinatorial manner.

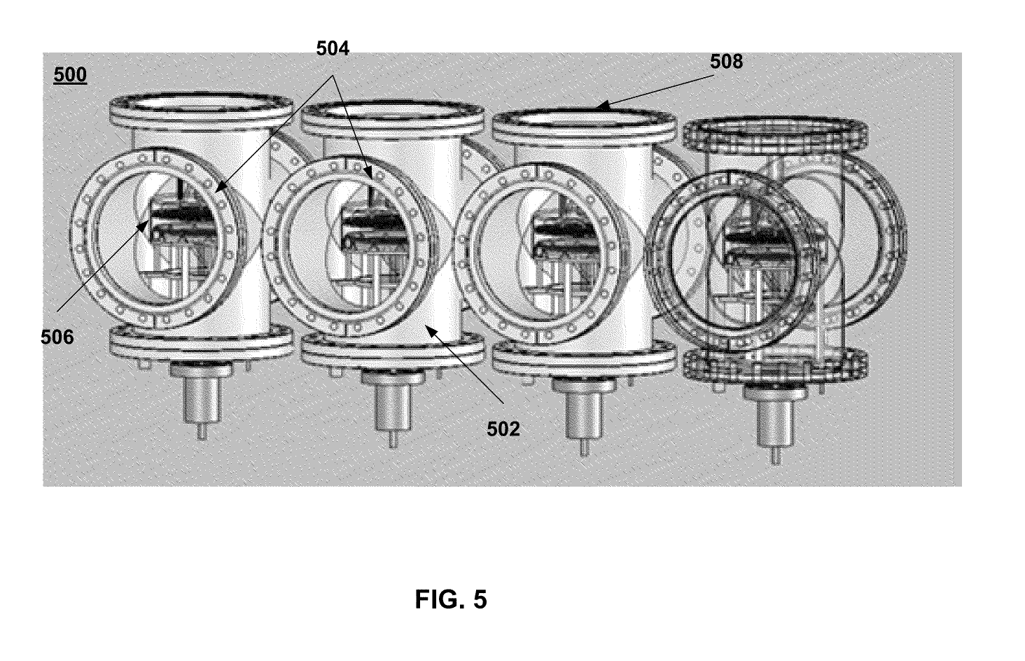

FIG. 5 is a schematic diagram for implementing high productivity combinatorial processing for MOCVD processes in accordance with some embodiments of the invention. FIG. 5 illustrates a plurality of modules, 500, that may be part of a HPC system. In contrast to the radial or “cluster tool” configuration as illustrated in FIG. 3, FIG. 5 illustrates a configuration wherein the various reaction cells are arranged in a linear configuration. That is, modules, 500, may be connected to a substrate handling system (not shown) that allows a linear geometry. For clarity, features on only one or two of the various modules in the figure will be identified. Those skilled in the art will understand that the four modules illustrated in FIG. 5 are symmetrical and will understand that each comprises the features being identified. Modules, 500, comprise chamber enclosures, 502, that define the vacuum environment. The module would connect with the system via the interface, 504. The interface allows substrates to pass between the module and the transfer chamber. Illustrated in FIG. 5 are four MOCVD reaction cells, 506, (i.e. one for each module) which will be described in more detail below. Although four are illustrated in FIG. 5, those skilled in the art will understand that any number of MOCVD reaction cells may be integrated into a system, limited only by practical considerations such as size, etc. The four reaction cells, 506, are independent and may be used to process substrates in a combinatorial manner. Parameters that may be varied combinatorially between the various reaction cells comprise material, temperature, gas flow rate, gas composition, rotation speed, etc. Furthermore, the substrates may be moved between the various modules and reaction cells to enable multilayer depositions. Also illustrated in FIG. 5 is a vacuum port, 508, which is connected to a vacuum system (not shown) that is used to control the pressure of the module. The basic architecture of the modules and supporting systems is well known in the art. The details of the reaction cells are novel and will be described in more detail below.

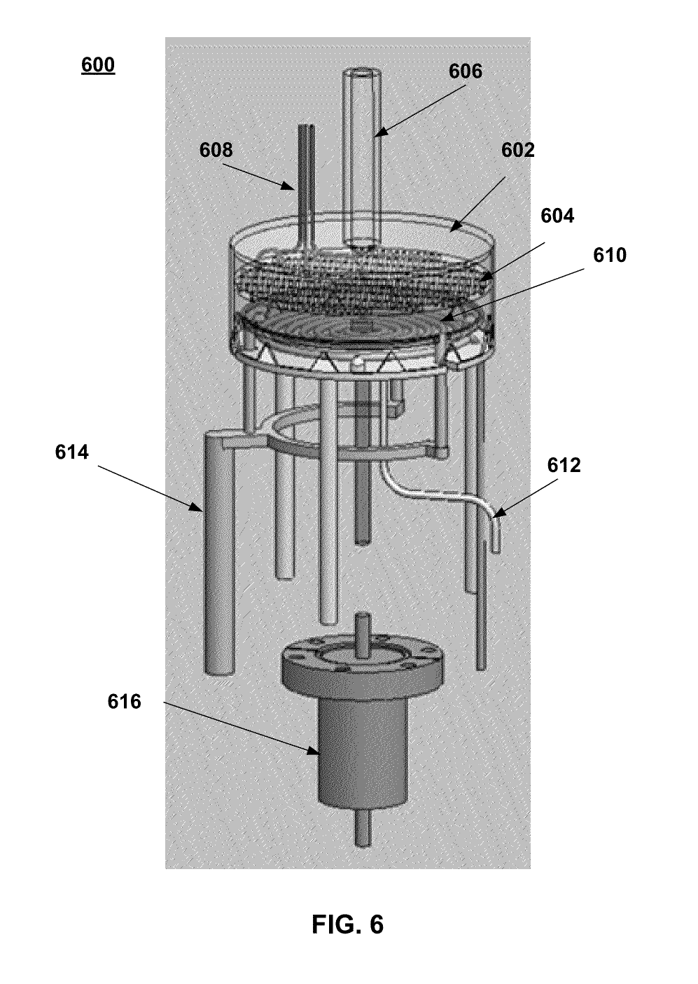

FIG. 6 is a schematic diagram for a single reactor cell, 600, for implementing high productivity combinatorial processing for MOCVD processes in accordance with some embodiments of the invention. FIG. 6 illustrates the details of the individual reaction cells (i.e. 406 in FIG. 4, and 506 in FIG. 5) incorporated in to the modules discussed with respect to FIGS. 4 and 5. Reaction cell, 600, comprises a gas delivery enclosure, 602, that is operable to isolate the reaction cell from the other reaction cells. Within gas delivery enclosure, 602, is a showerhead assembly, 604. The showerhead assembly may be designed to deliver one or more reactive gases as well as purge gases. Advantageously, the gas distribution manifolds within the showerhead assembly are separated so that the reactive gases do not react until they reach the substrate surface. Advantageously, the showerhead assembly is moveable in a vertical direction so that the spacing between the surface of the substrate and the lower surface of the showerhead can be varied as one of the combinatorial parameters. Typically, the showerhead does not require cooling or may be cooled with a fluid. The fluid may be any common cooling fluid such as a liquid or a gas. Advantageously, the cooling fluid is a gas. The reactive and purge gases are delivered to the showerhead using a gas delivery conduit, 606, as is known in the art. Fiber optic probes, 608, are integrated into the gas delivery enclosure, 602, and are used to monitor and control the temperature of the substrate and/or susceptor. The substrate (not shown) will be disposed on a susceptor (not shown) that will allow the susceptor and substrate to be heated using heating assembly, 610. Heating assembly, 610, may comprise any well known technology such as inductive heating, lamp heating, resistive heating, etc. Advantageously, the heating assembly uses an inductive heating technology. The substrate temperature may be one of the combinatorial parameters and may vary from about 500 C to about 1500 C. A conduit, 612, is used to deliver a cooling fluid to the susceptor. The fluid may be any common cooling fluid such as a liquid or a gas. Advantageously, the cooling fluid is a gas. Substrate lifting assembly, 614, is used in concert with a substrate transfer robot (314 in FIG. 3) to transfer substrates into and out of the reaction cell (and module) as is well known in the art. A vacuum compatible rotation feedthrough, 616, is used to apply rotation to the susceptor and substrate. The rotation speed may be one of the combinatorial parameters and may vary from 0 to about 2000 revolutions per minute (rpm).

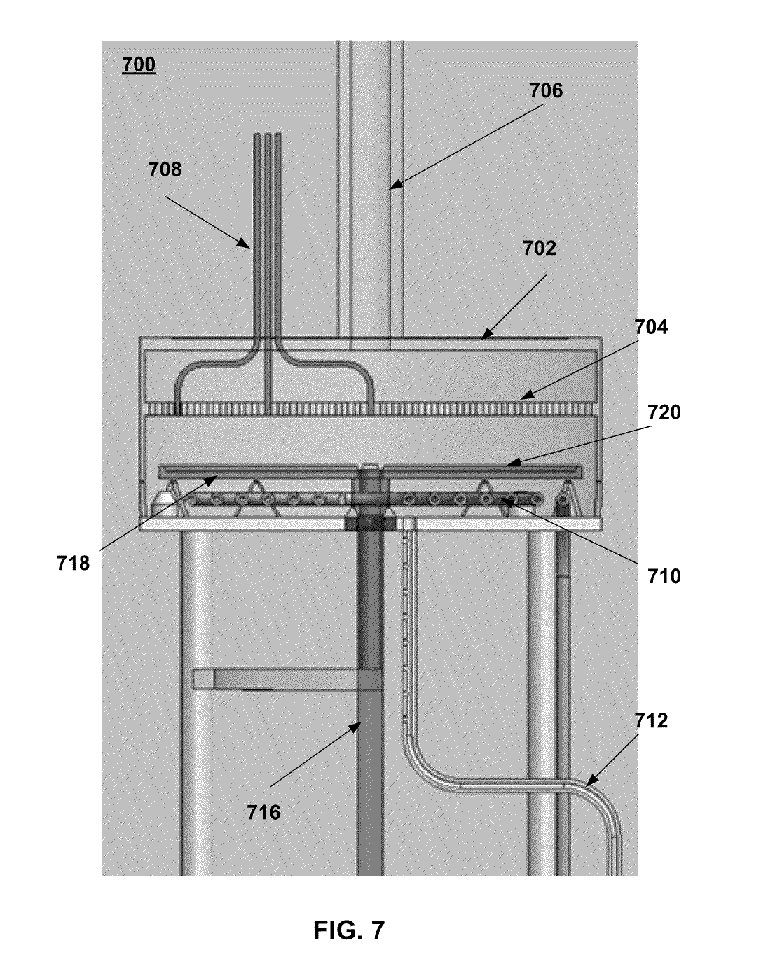

FIG. 7 is a schematic diagram for a single reactor cell for implementing high productivity combinatorial processing for MOCVD processes in accordance with some embodiments of the invention. FIG. 7 illustrates (in cross-section) the details of the individual reaction cells (i.e. 406 in FIG. 4, and 506 in FIG. 5) incorporated in to the modules discussed with respect to FIGS. 4 and 5. Reaction cell, 700, comprises a gas delivery enclosure, 702, that is operable to isolate the reaction cell from the other reaction cells. Within gas delivery enclosure, 702, is a showerhead assembly, 704. The showerhead assembly may be designed to deliver one or more reactive gases as well as purge gases. Advantageously, the gas distribution manifolds within the showerhead assembly are separated so that the reactive gases do not react until they reach the substrate surface. Advantageously, the showerhead assembly is moveable in a vertical direction so that the spacing between the surface of the substrate and the lower surface of the showerhead can be varied as one of the combinatorial parameters. Typically, the showerhead does not require cooling or may be cooled with a fluid. The fluid may be any common cooling fluid such as a liquid or a gas. Advantageously, the cooling fluid is a gas. The reactive and purge gases are delivered to the showerhead using a gas delivery conduit, 706, as is known in the art. Fiber optic probes, 708, are integrated into the gas delivery enclosure, 702, and are used to monitor and control the temperature of the substrate and/or susceptor. The substrate, 720, will be disposed on a susceptor, 718, that will allow the susceptor and substrate to be heated using heating assembly, 710. Heating assembly, 710, may comprise any well known technology such as inductive heating, lamp heating, resistive heating, etc. Advantageously, the heating assembly uses an inductive heating technology. The substrate temperature may be one of the combinatorial parameters and may vary from about 500 C to about 1500 C. A conduit, 712, is used to deliver a cooling fluid to the susceptor. The fluid may be any common cooling fluid such as a liquid or a gas. Advantageously, the cooling fluid is a gas. A vacuum compatible rotation feedthrough (not shown), is coupled to the susceptor with a shaft, 716, and is used to apply rotation to the susceptor and substrate. The rotation speed may be one of the combinatorial parameters and may vary from 0 to about 2000 revolutions per minute (rpm).

In the case of circular substrates and process cells with a circular shape, the reaction cells can range in size from about 50 mm (˜2 inches) in diameter to about 125 mm (˜5 inches) in diameter and still fit within the envelop of a process module designed to hold a 300 mm (˜12 inches) substrate. In this configuration, four independent reaction cells could be configured within the process module allowing four independent experiments to be conducted simultaneously. Currently, the largest semiconductor substrate in high volume production has a diameter of about 300 mm (˜12 inches). However, in the future, substrates with diameters as large as about 450 mm (˜18 inches) are envisioned; leading to larger process modules. The reaction cell structure of the present invention can be increased in scale to accommodate the larger substrate sizes.

Although the foregoing examples have been described in some detail for purposes of clarity of understanding, the invention is not limited to the details provided. There are many alternative ways of implementing the invention. The disclosed examples are illustrative and not restrictive.

What is claimed:

1. An apparatus comprising:
a module, wherein the module comprises a chamber enclosure, an interface, an exhaust system, and a vacuum port; and
a plurality of reaction cells disposed within the chamber enclosure,
wherein each of the reaction cells is operable to form a material on one of a plurality of substrates.

2. The apparatus of claim 1 wherein each of the plurality of reaction cells further comprises a showerhead assembly operable to deliver one or more gases to a surface of the substrate.

3. The apparatus of claim 1 wherein each of the plurality of reaction cells further comprises probes operable to measure a temperature of a surface of the substrate.

4. The apparatus of claim 1 wherein each of the plurality of reaction cells further comprises a susceptor operable for supporting the substrate.

5. The apparatus of claim 4 wherein each of the plurality of reaction cells further comprises a heating system operable for heating the susceptor.

6. The apparatus of claim 5 wherein the heating system is one of an inductive heating system, a lamp heating system, or a resistive heating system.

7. The apparatus of claim 6 wherein the heating system is an inductive heating system.

8. The apparatus of claim 5 wherein the heating system is operable to raise the temperature of the susceptor to a temperature in the range between about 500 C and about 1500 C.

9. The apparatus of claim 1 wherein the susceptor can rotate in each of the plurality of reaction cells.

10. The apparatus of claim 9 wherein the speed of rotation can be varied between 0 rpm and about 2000 rpm.

11. A method for forming a material on one or more substrates in a combinatorial manner comprising:
providing a module, wherein the module comprises a chamber enclosure, an interface, an exhaust system, and a vacuum port, and wherein the module further comprises a plurality of reaction cells disposed within the chamber enclosure, wherein each of the reaction cells is operable to form a material on one of a plurality of substrates; and
forming a material on the one or more substrates in a combinatorial manner by varying parameters of the forming between the plurality of reaction cells.

12. The method of claim 11 wherein the parameters of the forming a material comprise at least one of material, temperature, gas flow rate, gas composition, or rotation speed.

13. The method of claim 11 wherein each of the plurality of reaction cells forms the same material and at least one of temperature, gas flow rate, gas composition, or rotation speed is varied between the plurality of reaction cells in a combinatorial manner.

14. The method of claim 11 wherein each of the plurality of reaction cells forms a different material and a substrate is moved between the plurality of reaction cells to form a multilayer film stack.

15. The method of claim 14 wherein a sequence in which the substrate is moved between the plurality reaction cells is varied in a combinatorial manner.
